(19) United States
(12) Patent Application Publication
(10) Pub. No.: US 2025/0275421 A1
(43) Pub. Date: Aug. 28, 2025

(54) DISPLAY DEVICE AND METHOD FOR MANUFACTURING THE DISPLAY DEVICE

(71) Applicant: LG Display Co., Ltd., Seoul (KR)

(72) Inventors: MiRae LEE, Sejong-si (KR); Jieun LEE, Goyang-si (KR); Youngsoo LEE, Chilgok-gun (KR)

(73) Assignee: LG Display Co., Ltd., Seoul (KR)

(21) Appl. No.: 18/818,283

(22) Filed: Aug. 28, 2024

(30) Foreign Application Priority Data
Feb. 26, 2024 (KR) 10-2024-0027378

(51) Int. Cl. H10K 59/80; H10K 59/12; H10K 59/131; H10K 59/40

(52) U.S. Cl. CPC H10K 59/873; H10K 59/1201; H10K 59/131; H10K 59/40

(57) ABSTRACT

A display device may include a first area in which a pixel array is disposed; a second area in which a drive circuit configured to operate the pixel array is disposed, the second area being positioned outside the first area; and a third area in which a plurality of dams and a plurality of lines are disposed, the third area being positioned outside the second area, in which a plurality of protruding patterns is formed outside at least one of the plurality of lines. A method for manufacturing a display device is also disclosed.

### CROSS-REFERENCE TO RELATED APPLICATIONS

This application claims the benefit of and priority to Korean Patent Application No. 10-2024-0027378 filed on Feb. 26, 2024, the entire contents of which are incorporated herein by reference for all purposes.

### BACKGROUND

### 1. Technical Field

The present disclosure relates to a display device, and more particularly to, for example, without limitation, a display device capable of improving element reliability of the display device.

### 2. Description of the Related Art

Recent display devices, which are capable of displaying various pieces of information and interacting with users who receive the corresponding information, are required to have various sizes, various shapes, and various functions.

Examples of display devices include a liquid crystal display (LCD) device, an electrophoretic display device (FPD), a light-emitting diode (LED) display device, and the like.

The light-emitting display device is a spontaneous light-emitting display device. The light-emitting display device may be manufactured as a lightweight, thin display device because the light-emitting display device does not require a separate light source, unlike the liquid crystal display (LCD) device. In addition, the light-emitting display device is advantageous in terms of power consumption because the light-emitting display device operates at a low voltage. Further, the light-emitting display device is studied as a next-generation display device because the light-emitting display device is excellent in color implementation, a response speed, a viewing angle, and a contrast ratio (CR).

In case that the light-emitting display device is an organic light-emitting display device, a light-emitting element layer may be an organic light-emitting element layer including an anode electrode, a light-emitting layer, and a cathode electrode. In addition, quantum-dot light-emitting diodes (QLEDs) including quantum dots (QDs) may be further used for the light-emitting element layer. Hereinafter, the description will be made on the assumption that the light-emitting display device is an organic light-emitting display device. However, the type of light-emitting element layer is not limited thereto.

The organic light-emitting display device displays information on a screen by emitting light by using a plurality of pixels including light-emitting element layers having light-emitting layers. Depending on how to operate the pixels, the organic light-emitting display devices may be classified into an active matrix type organic light-emitting diode display (AMOLED) and a passive matrix type organic light-emitting diode display (PMOLED).

The active matrix type organic light-emitting diode display (AMOLED) displays images by controlling currents flowing to organic light-emitting diodes by using thin-film transistors (TFTs).

The active matrix type organic light-emitting diode display may include various thin-film transistors including a switching thin-film transistor (switching TFT), a driving TFT connected to the switching TFT, and an organic light-emitting diode (OLED) connected to the driving TFT.

A plurality of drive circuits may be disposed in a display area of a substrate to control an operation of a light-emitting element layer. The light-emitting element layer may be electrically connected to the drive pixel. The drive circuit may supply the light-emitting element layer with a drive current, which corresponds to a data signal, in response to a scan signal. For example, the plurality of drive circuits may include a plurality of thin-film transistors and a plurality of storage capacitors.

Different types of semiconductor patterns or hybrid thin-film transistors may be disposed as the plurality of thin-film transistors. Different types of semiconductor patterns, e.g., polycrystalline semiconductor patterns, which are made of low-temperature polysilicon (LTPS) materials, and oxide semiconductor patterns, which are made of oxides, may be used.

However, a channel area of an oxide semiconductor may become conductive because of the penetration of moisture from the outside, which may degrade element characteristics.

The description of the related art should not be assumed to be prior art merely because it is mentioned in or associated with this section. The description of the related art includes information that describes one or more aspects of the subject technology, and the description in this section does not limit the invention.

### SUMMARY

In one or more aspects, an object to be achieved by the present disclosure is to provide a display device capable of minimizing a moisture penetration effect.

In one or more aspects, another object to be achieved by the present disclosure is to provide a display device capable of promoting post-process stability.

Objects of the present disclosure are not limited to the above-mentioned objects, and other objects, which are not mentioned above, can be clearly understood by those skilled in the art from the following descriptions.

In order to achieve the above-mentioned objects, a display device according to one or more example embodiments of the present disclosure may include: a first area in which a pixel array is disposed; a second area in which a drive circuit configured to operate the pixel array is disposed, the second area being positioned outside the first area; and a third area in which a plurality of dams and a plurality of lines are disposed, the third area being positioned outside the second area, in which a plurality of protruding patterns is formed outside at least one of the plurality of lines.

Other detailed matters of the example embodiments are included in the detailed description and the drawings.

According to one or more aspects of the present disclosure, it is possible to improve the reliability of the display device by maximally delaying the moisture penetration that occurs through the outer surfaces of the plurality of protruding patterns.

According to one or more aspects of the present disclosure, it is possible to minimize the process level difference, thereby improving the yield of the process of processing the encapsulation layer and the touch electrode that is the post-process.

According to one or more aspects of the present disclosure, the empty space between the protruding pattern and the dam, which are adjacent to each other, may be removed, which may improve the yield of the process of processing the encapsulation layer and the touch electrode that is the post-process.

The effects according to one or more aspects of the present disclosure are not limited to the contents exemplified above, and more various effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a block diagram illustrating a display device according to an example embodiment of the present disclosure;

FIG. 2 is a circuit diagram of a pixel array of the display device according to the example embodiment of the present disclosure;

FIG. 3 is a cross-sectional view of the display device according to the example embodiment of the present disclosure;

FIG. 4 is an enlarged top plan view of area A illustrated in FIG. 1;

FIG. 5 is a cross-sectional view taken along line V-V′ illustrated in FIG. 4;

FIG. 6 is a cross-sectional view taken along line VI-VI′ illustrated in FIG. 4;

FIG. 7 is a cross-sectional view taken along line VII-VII′ illustrated in FIG. 4;

FIG. 8 is an enlarged top plan view of area B illustrated in FIG. 4;

FIG. 9 is a cross-sectional view taken along line IX-IX′ illustrated in FIG. 8; and

FIG. 10 is a view illustrating another type of protruding pattern of the display device according to the example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B. For example, the phrase “source/drain” may be understood as source and/or drain, or may be understood as only source; only drain; source or drain; or source and drain.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

In the present disclosure, the term “device” may mean a display device such as a liquid crystal module (LCM) and an organic light-emitting diode display module (OLED Module) that includes a display panel and a drive part for operating the display panel. Further, the term “device” may also mean a set electronic apparatus or a set device (or set apparatus) such as a notebook computer, a television, a computer monitor, an automotive apparatus, an equipment apparatus including components for a vehicle or automobile, a mobile electronic apparatus such as a smartphone or electronic pad that are finished products (complete products or final products) including the LCM, the OLED module, and the like.

Therefore, the device according to one or more aspects of the present disclosure may mean the display device itself such as the LCM or the OLED module, the application product including the LCM, the OLED module, and the like, or a set apparatus that is a final consumer device.

Further, in several example embodiments, the LCM or the OLED module, which includes the display panel, the drive part, and the like, may be expressed as a “display device”. Further, the electronic device, which is the finished product including the LCM and the OLED module may be expressed as the “set apparatus” that is distinguished from the display device. For example, the display device may include a liquid crystal (LCD) or organic light-emitting (OLED) display panel, and a source PCB that is a controller for operating the display panel. The set apparatus may further include a set PCB that is a set controller electrically connected to the source PCB and configured to operate the entire set apparatus.

The display panel used in the example embodiment of the present disclosure may be any form of display panel, such as a liquid crystal display panel, an organic light emitting diode (OLED) display panel, and an electroluminescent display panel. The example embodiment is not limited thereto. For example, the display panel may be a display panel that may generate a sound by being vibrated by a vibration device according to the example embodiment of the present disclosure. The display panel applied to the display device according to the example embodiment of the present disclosure is not limited to a shape or size of the display panel.

Respective features of several example embodiments of the present disclosure may be partially or entirely coupled to or combined with each other, and various technical cooperation and operations may be made, and the respective example embodiments may be carried out independently of each other or carried out together correlatively.

Hereinafter, the example embodiment of the present disclosure will be described with reference to the accompanying drawings and example embodiments. The scales of the constituent elements illustrated in the drawings are different from actual scales for convenience of description. Therefore, the present invention is not limited to the scales illustrated in the drawings.

Hereinafter, various example embodiments of the present disclosure will be described in detail with reference to the drawings.

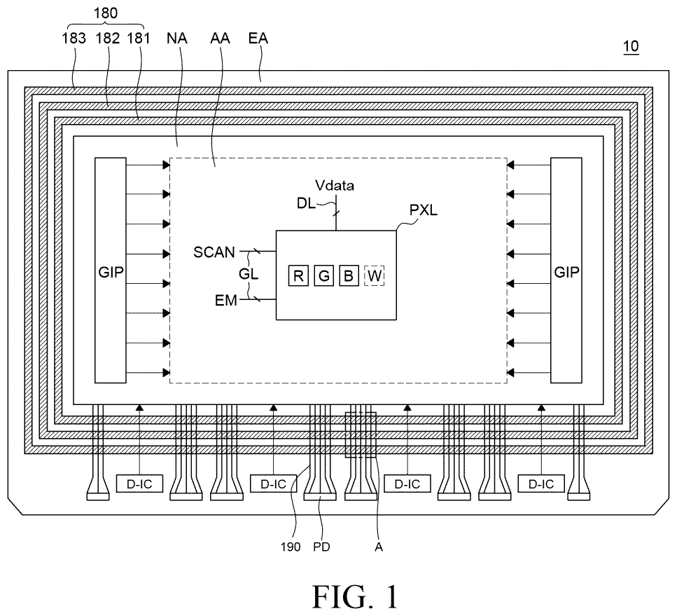

FIG. 1 is a block diagram illustrating a display device according to an example embodiment of the present disclosure.

A display device 10 may include a plurality of areas. For example, the display device 10 includes a first area AA that is a display area in which at least one image is displayed. A pixel array PXL is formed in the display area AA on a display. Second areas NA, which are one or more non-display areas may be provided on an outer portion of the first area AA. For example, the second area NA may be adjacent to one or more side surfaces of the first area AA.

A third area EA, which is an end of the display device 10, may be disposed outside the second area NA.

With reference to FIG. 1, the second area NA may surround the rectangular first area AA, and the third area EA may be positioned outside the second area NA. However, it should be understood that the shapes of the first area AA and the arrangement of the second areas NA adjacent to the first area AA are not specifically limited to the example display device 10 illustrated in FIG. 1. The first area AA and the second area NA may define any shape of the display device 10. Non-restrictive examples of the shapes may include a pentagonal shape, a hexagonal shape, a circular shape, an elliptical shape, and the like. The example embodiment of the present disclosure is not limited thereto.

The pixels PXL in the first area AA may be respectively related to pixel circuits each including one or more TFTs manufactured on a substrate of the display device 10. The pixel circuits may each be electrically connected to one or more drive circuits. For example, the pixel circuit may be electrically connected to a gate line GL and a data line DL to perform communication with a gate driver GIP, which is positioned in the second area NA of the display device 10, and a data driver D-IC positioned in the third area EA.

The one or more drive circuits may be implemented by TFTs configured in the second area NA illustrated in FIG. 1. For example, the gate driver GIP may be implemented by using a plurality of TFTs on the substrate of the display device 10. Non-restrictive examples of the circuits configured as the TFTs of the substrate may include an inverter circuit, a multiplexer, an electrostatic discharge (ESD) circuit, and the like. The example embodiment of the present disclosure is not limited thereto.

Some of the drive circuits may be provided as integrated circuit (IC) chips and mounted in the second area NA or the third area EA of the display device 10 by using a chip-on-glass (COG) method or other similar methods. In addition, some of the drive circuits may be mounted on another substrate and coupled to connection interfaces (pads, bumps, or pins) disposed in the second area NA or the third area EA by using a printed circuit, such as a flexible printed circuit board (PCB), chip-on-film (COF), tape-carrier-package (TCP), or other suitable technologies.

In the example embodiments of the present disclosure, at least two different type TFTs are used for a TFT substrate for the display. The types of TFTs, which are adopted to some of the pixel circuits and some of the drive circuits, may vary depending on the requirement of the display.

For example, the pixel circuit may also be implemented by TFTs, which have oxide active layers, and TFTs that have poly-Si active layers (LTPS TFTs). Meanwhile, the drive circuit is implemented by TFTs having poly-Si active layers (LTPS TFTs). Unlike the LTPS TFTs, the oxide TFTs do not cause a problem of fluctuation of pixel-pixel (from-pixel-to-pixel) threshold voltages generated by a large area. Uniform Vth may be acquired even in an array of pixel circuits for the large-scale display. The problem with Vth uniformity between the TFTs for implementing the drive circuit may be less affected directly by the brightness uniformity of the pixels.

Factors targeted for the drive circuits (e.g., GIP) may include a size of the drive circuit for reducing a size of a bezel and/or an ability for providing scan signals at high speed.

Signals and data may be provided to the pixels by using the drive circuits on the substrate to be implemented by the LTPS TFTs with higher clocks than a case in which all the TFTs in the TFT panel are formed as the oxide TFTs. Therefore, the display, which may operate at high speed, may be provided without a blur. For example, the advantages of the oxide TFT and the LTPS TFT are combined with the design of the TFT panel.

The gate driver GIP may be provided with a SCAN circuit connected to a switching transistor of the pixel PXL and configured to transmit a scan signal SCAN for turning on or off the switching transistor, and an EM circuit configured to supply a light-emitting signal EM to the pixel PXL.

Further, the third area EA, which is the end of the display device 10, may be an area in which the display device is sealed by using an encapsulation layer and a plurality of dams 180.

The plurality of dams 180 includes a first dam 181, a second dam 182, and a third dam 183 and suppresses an overflow of the encapsulation layer.

The first dam 181, the second dam 182, and the third dam 183 may each be disposed to surround the second area NA. Further, the second dam 182 may be disposed outside the first dam 181, and the third dam 183 may be disposed outside the second dam 182.

Further, a plurality of lines 190 may be disposed in the third area EA. Specifically, in the third area EA, the plurality of lines 190 may be disposed to intersect the plurality of dams 180.

Further, the plurality of lines 190 may be connected to pads PD and receive inspection signals for inspecting the pixel PXL disposed in the first area AA. However, the signals applied to the plurality of lines 190 may include not only the inspection signals but also various signals for operating the display device 10.

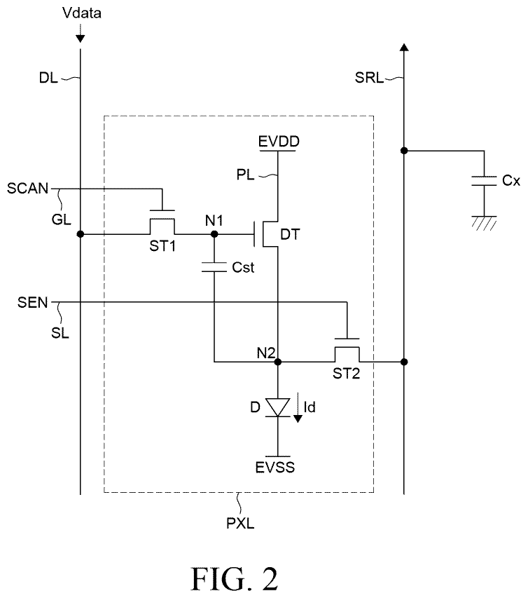

FIG. 2 is a circuit diagram of the pixel array of the display device according to the example embodiment of the present disclosure. FIG. 2 exemplarily illustrates the display device having a 3T1C structure including three thin-film transistors and a single storage capacitor. However, the display device of the present disclosure is not limited to the structure. Various structures, such as 4T1C, 5T1C, 6T1C, 7T1C, 8T1C, 4T2C, 5T2C, 6T2C, 7T2C, and 8T2C structures, may be applied.

With reference to FIG. 2, the display device according to the example embodiment of the present disclosure may include the gate line GL, the data line DL, a power line PL, and a sensing line SL. Each subpixel SP may include a first switching thin-film transistor ST1, a second switching thin-film transistor ST2, a driving thin-film transistor DT, a light-emitting element D, and a storage capacitor Cst. The example embodiments of the present disclosure are not limited thereto.

The light-emitting element D includes an anode electrode connected to a second node N2, a cathode electrode connected to an input end of a low-potential drive voltage EVSS, and a light-emitting element layer positioned between the anode electrode and the cathode electrode. The light-emitting element D may be an organic light-emitting element. The example embodiments of the present disclosure are not limited thereto.

The driving thin-film transistor DT may control a current Id flowing to the organic light-emitting element D in accordance with a voltage Vgs between a gate and a source. The driving thin-film transistor DT may include a gate electrode connected to a first node N1, a drain electrode connected to the power line PL and configured to provide a high-potential drive voltage EVDD, and a source electrode connected to the second node N2.

The storage capacitor Cst is connected between the first node N1 and the second node N2. The storage capacitor Cst may maintain a predetermined voltage for a single frame.

The first switching thin-film transistor ST1 turns on the driving thin-film transistor DT by applying a data voltage Vdata to the first node N1 applied to the data line DL in response to a gate signal SCAN when the display panel operates. In this case, the first switching thin-film transistor ST1 may include a gate electrode connected to the gate line GL and configured to receive the gate signal SCAN, a drain electrode connected to the data line DL and configured to receive the data voltage Vdata, and a source electrode connected to the first node N1.

The second switching thin-film transistor ST2 stores a source voltage of the second node N2 in a sensing capacitor Cx of a sensing voltage read-out line SRL by switching the current between the second node N2 and the sensing voltage read-out line SRL in response to a sensing signal SEN. The second switching thin-film transistor ST2 resets the source voltage of the driving thin-film transistor DT to an initialization voltage by switching the current between the second node N2 and the sensing voltage read-out line SRL in response to the sensing signal SEN when the display panel operates. In this case, the gate electrode of the second switching thin-film transistor ST2 is connected to the sensing line SL, the drain electrode is connected to the second node N2, and the source electrode is connected to the sensing voltage read-out line SRL.

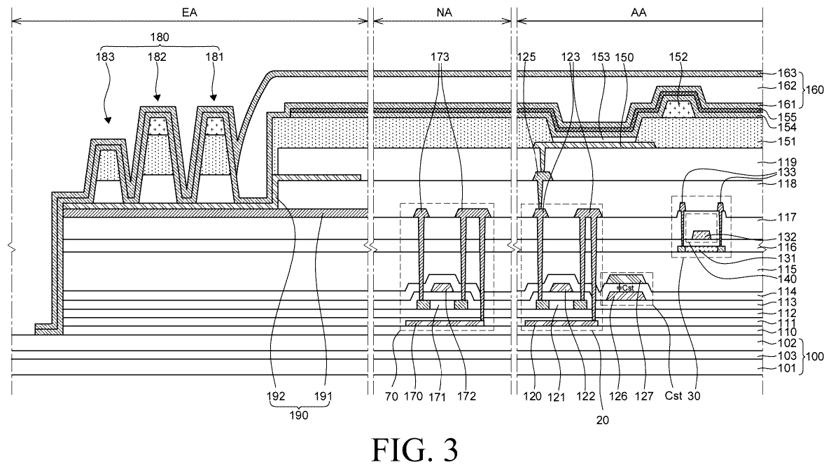

FIG. 3 is a cross-sectional view of the display device according to the example embodiment of the present disclosure.

The display device 10 according to the example embodiment of the present disclosure is formed on a substrate 100 including a first substrate 101, a second substrate 102, and an intermediate layer 103 provided between the first substrate 101 and the second substrate 102.

The first substrate 101 and the second substrate 102 may be made of at least one of polyimide, polyethersulfone, polyethylene terephthalate, and polycarbonate. The example embodiments of the present disclosure are not limited thereto. In case that the substrate 100 is made of a plastic material, a process of manufacturing the display device may be performed in a state in which a support substrate made of glass is disposed below the substrate, and the support substrate may be released after the process of manufacturing the display device 10 is completed. In addition, after the support substrate is released, a backplate (or plate) for supporting the substrate may be disposed below the substrate. In case that the substrate is made of a plastic material, moisture may penetrate into the substrate and the moisture penetration is performed to a thin-film transistor or a light-emitting element layer, which may degrade the performance of the display device. The display device 10 according to the example embodiment of the present disclosure may include the two substrates, i.e., the first and second substrates 101 and 102 made of a plastic material in order to suppress the degradation of the performance of the display device 10 caused by the moisture penetration. Further, the intermediate layer 103, which is an inorganic film, may be formed between the first substrate 101 and the second substrate 102 to inhibit moisture from penetrating into the substrate, thereby improving the performance and reliability of the product. The intermediate layer 103 may be configured by an inorganic film. For example, the intermediate layer 103 may be configured as a single layer or multilayer made of silicon nitride SiNx or silicon oxide SiOx. The example embodiment is not limited thereto.

The display device formed on the substrate 100 may include a plurality of areas. In the present disclosure, the first area AA, the second area NA, and the third area EA are provided. However, the example embodiment is not limited thereto.

A first buffer layer 110 may be disposed on a surface of the substrate 100 in the first area AA, the second area NA, and the third area EA. The buffer layer 110 may serve to improve bonding forces between the substrate and layers formed on the buffer layer and suppress various types of defects, such as a leak of an alkaline material from the first substrate 101 and the second substrate 102. In addition, the buffer layer 110 may delay the diffusion of moisture or oxygen penetrating into the first substrate 101 and the second substrate 102.

The buffer layer 110 may be configured as a single layer or multilayer made of silicon nitride SiNx or silicon oxide SiOx. In case that the buffer layer 110 is configured as a multilayer, silicon oxide SiOx and silicon nitride SiNx may be formed alternately.

The buffer layer 110 may be excluded depending on the type and material of the substrate, the structure and type of the thin-film transistor, and the like.

The transistors in the first area AA and the second area NA are formed on the buffer layer 110. The transistors in the first area AA may include first and second transistors 20 and 30 that are switching transistors or driving transistors for operating the pixels PXL, and the transistors in the second area NA may include a third transistor 70 for operating the gate driver GIP.

A first blocking layer 120 may be disposed on the buffer layer 110 in the first area AA and the second blocking layer 170 may be disposed on the buffer layer 110 in the second area NA. The first blocking layer 120 may have an area larger than an area of a semiconductor pattern formed after the first blocking layer 120 is formed. The second blocking layer 170 may have an area larger than an area of a semiconductor pattern formed after the second blocking layer 170 is formed.

The first blocking layer 120 and the second blocking layer 170 may inhibit light, which is introduced from the outside of the display device 10, from reaching the semiconductor pattern and causing an erroneous operation of the semiconductor pattern.

The first blocking layer 120 and the second blocking layer 170 may suppress a problem of the introduction of electric charges from the substrate 100. For example, in case that the voltage is applied to the gate electrode of the thin-film transistor over a long period of time, the electric charges of the substrate are introduced into a channel area of the semiconductor pattern of the transistor by an electric field generated in the transistor, which may cause a fluctuation of a charge quantity in the corresponding channel area (back channel phenomenon). The electric charges may be positive holes or electric charges depending on polarities of the electric field. The substrate may change the current of the transistor and cause a change in threshold voltage of the thin-film transistor. This may cause a change in brightness of the pixel and afterimages. Therefore, the blocking layer may be disposed between the substrate and the semiconductor pattern and block the undesired introduction of electric charges into the transistor from the substrate, thereby suppressing the fluctuation of threshold voltages Vth of the transistor and suppressing afterimages. The stability of the transistor may be ensured during the operation, and the display quality may be improved.

The first blocking layer 120 and the second blocking layer 170 may be disposed by using an opaque electrically conductive material to block light introduced from the outside of the display device 10. For example, the first blocking layer 120 may be configured as a single layer or multilayer made of any one of molybdenum (Mo), copper (Cu), titanium (Ti), aluminum (Al), chromium (Cr), gold (Au), nickel (Ni), neodymium (Nd), tungsten (W), and gold (Au) or an alloy thereof. The example embodiment is not limited thereto.

The first blocking layer 120 and the second blocking layer 170 may include titanium (Ti) that stably bonds with hydrogen. The first blocking layer 120 may inhibit hydrogen, which remains between the substrate 100 and the insulation film during the process of forming the semiconductor pattern, from penetrating into the semiconductor pattern. Therefore, the first blocking layer 120 inhibits the semiconductor pattern from becoming conductive, which may improve reliability related to operating characteristics of the thin-film transistor of the display device according to the example embodiment of the present disclosure.

A second buffer layer 111 and a third buffer layer 112 may be disposed above the first blocking layer 120 and disposed on the first buffer layer 110 in the first area AA, the second area NA, and the third area EA. The second buffer layer 111 and the third buffer layer 112 may be made of an insulating material such as silicon nitride SiNx or silicon oxide SiOx. In addition, the second buffer layer 111 and the third buffer layer 112 may be made of an insulating inorganic material or the like. The example embodiments of the present disclosure are not limited thereto.

A first semiconductor pattern 121 of the first transistor 20 may be disposed on the second buffer layer 111 and the third buffer layer 112 in the first area AA at positions that overlap the first blocking layer 120, and a third semiconductor pattern 171 of the third transistor 70 may be disposed on the second buffer layer 111 and the third buffer layer 112 in the first area AA and the second area NA and disposed at positions that overlap the second blocking layer 170.

The first semiconductor pattern 121 and the third semiconductor pattern 171 may be made of a polycrystalline semiconductor. For example, the polycrystalline semiconductor may be made of a low-temperature polysilicon (LTPS) with high mobility. In case that the first semiconductor pattern 121 and the third semiconductor pattern 171 are made of the polycrystalline semiconductor, energy power consumption is low, and reliability is excellent.

In addition, the first semiconductor pattern 121 and the third semiconductor pattern 171 may be made of amorphous silicon (a-Si), various organic semiconductor materials such as pentacene, or oxide. The example embodiment is not limited thereto.

The first semiconductor pattern 121 and the third semiconductor pattern 171 may include channel areas without being subjected to a doping process. The channel areas may be disposed to overlap a first gate electrode 122 and a third gate electrode 172. Source and drain areas, which have become conductive by an ion doping process, may be provided at two opposite sides of the channel area. The source and drain areas may be portions of the first and third semiconductor patterns 121 and 171 connected to a first source/drain electrode 123 and a third source/drain electrode 173.

A first gate insulation film 113 may be disposed on the first semiconductor pattern 121 and the third semiconductor pattern 171. Because the first gate insulation film 113 is disposed between the first semiconductor pattern 121 and the first gate electrode 122 of the first transistor 20 and between the third semiconductor pattern 171 and the third gate electrode 172 of the third transistor 70, the first gate insulation film 113 may insulate the first semiconductor pattern 121 and the first gate electrode 122 and insulate the third semiconductor pattern 171 and the third gate electrode 172.

The first gate insulation film 113 may be made of an insulating inorganic material such as silicon nitride SiNx or silicon oxide SiOx or made of an insulating organic material or the like. The example embodiments of the present disclosure are not limited thereto.

The first gate electrode 122 and the third gate electrode 172 of the first transistor 20 and the third transistor 70 may be disposed on the first gate insulation film 113, and a first storage capacitor electrode 126 of the storage capacitor Cst of the pixel PXL in the first area AA may be disposed on the first gate insulation film 113.

The first gate electrode 122 may be disposed to overlap the first semiconductor pattern 121, and the third gate electrode 172 may be disposed to overlap the third semiconductor pattern 171.

The first gate electrode 122, the third gate electrode 172, and the first storage capacitor electrode 126 may each be configured as a single layer or multilayer made of any one of silver (Ag) molybdenum (Mo), copper (Cu), titanium (Ti), aluminum (Al), chromium (Cr), gold (Au), nickel (Ni), neodymium (Nd), tungsten (W), and gold (Au) or an alloy thereof. The example embodiment is not limited thereto.

A first interlayer insulation film 114 may be disposed on the first gate electrode 122, the third gate electrode 172, and the first storage capacitor electrode 126.

A second capacitor electrode 127 may be disposed on the first interlayer insulation film 114 and overlap the first storage capacitor electrode 126, such that the storage capacitor Cst may be formed.

The second storage capacitor electrode 127 may be configured as a single layer or multilayer made of any one of silver (Ag) molybdenum (Mo), copper (Cu), titanium (Ti), aluminum (Al), chromium (Cr), gold (Au), nickel (Ni), neodymium (Nd), tungsten (W), and gold (Au) or an alloy thereof. The example embodiment is not limited thereto.

A first insulation film 115 may be disposed above the second storage capacitor electrode 127. The first insulation film 115 may be made of an insulating material such as silicon nitride SiNx or silicon oxide SiOx or made of an insulating organic material or the like. The example embodiments of the present disclosure are not limited thereto.

The second transistor 30 may be disposed above the first insulation film 115.

A second semiconductor pattern 131 of the second transistor 30 may be disposed above the first insulation film 115. The second semiconductor pattern 131 may be made of metal oxide, e.g., any one of indium-gallium-zinc oxide (IGZO), indium-zinc oxide (IZO), indium-gallium-tin oxide (IGTO), and indium-gallium oxide (IGO). The example embodiment is not limited thereto.

The conductive properties of the metal oxide material may be improved by a doping process that injects impurities. The second semiconductor pattern 131 may include a channel area that defines a channel through which electrons or positive holes move. In addition, the channel area may be disposed to overlap a second gate electrode 132. Source/drain electrode areas, which have become conductive, may be provided at two opposite sides of the channel area. The source/drain electrode area may be a portion of the second semiconductor pattern 131 connected to a second source/drain electrode 133.

A second gate insulation film 116 may be disposed above the second semiconductor pattern 131. The second gate insulation film 116 may be made of an insulating material such as silicon nitride SiNx or silicon oxide SiOx or made of an insulating inorganic material, an organic material, or the like. The example embodiments of the present disclosure are not limited thereto.

The second gate electrode 132 may be disposed on the second gate insulation film 116 and disposed in an area that overlaps the channel area of the second semiconductor pattern 131.

A second interlayer insulation film 117 may be disposed above the second gate electrode 132. The second interlayer insulation film 117 may be made of an insulating material such as silicon nitride SiNx or silicon oxide SiOx or made of an insulating inorganic material, an organic material, or the like. The example embodiments of the present disclosure are not limited thereto.

The first source/drain electrode 123, the second source/drain electrode 133, and the third source/drain electrode 173, which are source/drain electrodes of the first transistor 20, the second transistor 30, and the third transistor 70, may be disposed above the second interlayer insulation film 117. The first source/drain electrode 123 and the third source/drain electrode 173 may be respectively connected to the first semiconductor pattern 121 and the third semiconductor pattern 171 through contact holes formed in the second interlayer insulation film 117, the second gate insulation film 116, the first insulation film 115, the first interlayer insulation film 114, and the first gate insulation film 113.

The second source/drain electrode 133 and the second semiconductor pattern 132 may be connected through contact holes formed in the second interlayer insulation film 117 and the second gate insulation film 116.

The first blocking layer 120 may be connected to the first source/drain electrode 123, and a second blocking layer 170 may be connected to the third source/drain electrode 173. In case that the first blocking layer 120 and the second blocking layer 170 are respectively connected to the first source/drain electrode 123 and the third source/drain electrode 173, it is possible to block light to the first semiconductor pattern 121 and the third semiconductor pattern 171, suppress a situation in which a drain current rapidly increases as parasitic carriers accumulate on the first semiconductor pattern 121 and the third semiconductor pattern 171, and suppress a change in threshold voltage caused by the drain voltage.

The second blocking layer 170 may be connected to the third source/drain electrode 173. However, because a size of the transistor of the gate driver is larger than a size of the transistor of the pixel of the drive pixel, a change in operation of the semiconductor layer made by a size ratio is small, such that the second blocking layer 170 and the second source/drain electrode 73 may not be connected.

A first planarization layer 118 and a second planarization layer 119 may be disposed above the first source/drain electrode 123, the second source/drain electrode 132, and the third source/drain electrode 173. A connection electrode 125 may be disposed between the first planarization layer 118 and the second planarization layer 119.

An anode electrode 150 may be disposed on the second planarization layer 119. The anode electrode 150 may be connected to the connection electrode 125 through a hole formed in the first planarization layer 118.

A contact hole may be formed in the first planarization layer 118, and the connection electrode 125 may be disposed in the contact hole, such that the first transistor 20 and the anode electrode 150 may be electrically connected through the connection electrode 125.

The anode electrode 150 may serve to supply positive holes to a light-emitting element layer 153 and be made of an electrically conductive material with a high work function.

In case that the display device 10 is a top-emission type display device, the anode electrode 150 may serve as a reflective electrode configured to reflect light and be disposed by using an opaque electrically conductive material. For example, the anode electrode 150 may be made of at least one of silver (Ag), aluminum (Al), gold (Au), molybdenum (Mo), tungsten (W), chromium (Cr), and an alloy thereof. The example embodiments of the present disclosure are not limited thereto. For example, the anode electrode 150 may have a three-layer structure including silver (Ag), lead (PD), and copper (Cu). The example embodiment is not limited thereto.

In case that the display device 10 is a bottom-emission type display device, the anode electrode 150 may be disposed by using a transparent electrically conductive material that transmits light. For example, the anode electrode 150 may be made of at least one of indium-tin oxide (ITO) and indium-zinc oxide (IZO). The example embodiments of the present disclosure are not limited thereto.

A bank layer 151 may be disposed on the anode electrode 150 and the second planarization layer 119.

The bank layer 151 may separate the plurality of subpixels SP, minimize light blurring, and suppress a color mixture at various viewing angles.

The bank layer 151 may overlap an end of the anode electrode 150 while exposing the anode electrode 150 corresponding to the light-emitting area.

In addition, the bank layer 151 may overlap a hole formed in the first planarization layer 118 and a hole formed in the second planarization layer 119.

The bank layer 151 may be made of at least one of the materials including inorganic insulating materials, such as silicon nitride SiNx or silicon oxide SiOx, or organic insulating materials such as BenzoCycloButene (BCB), acrylic resin, epoxy resin, phenolic resin, polyamide resin, or polyimide resin. The example embodiment is not limited thereto.

A spacer 152 may be further disposed on the bank layer 151. The spacer 152 may compensate for an empty space between an upper substrate and the substrate 100 having the light-emitting element layer 153, thereby minimizing damage to the display device 10 caused by an impact from the outside. The spacer 152 may be made of the same material as the bank layer 151 and formed simultaneously with the bank layer 151. The example embodiment is not limited thereto.

The light-emitting element layer 153 may be disposed on the anode electrode 150, the bank layer 151, and the spacer 152. The light-emitting element layer 153 may include one or more of a red light-emitting layer, a green light-emitting layer, a blue light-emitting layer, and a white light-emitting layer to emit light with a particular color. In case that the light-emitting element layer 153 includes the white organic light-emitting layer, a color filter may be disposed above the light-emitting element layer 153 to convert white light, which is emitted from the white organic light-emitting layer, into light with another color. In addition, the light-emitting element layer 153 may further include a hole injection layer, a hole transport layer, an electron transport layer, an electron injection layer, and the like, in addition to the organic light-emitting layer. The example embodiment is not limited thereto.

A cathode electrode 154 may be disposed on the light-emitting layer 153. The cathode electrode 154 may serve to supply electrons to the light-emitting element layer 153 and be made of an electrically conductive material with a low work function.

In case that the display device 10 is a top-emission type display device, the cathode electrode 154 may be disposed by using a transparent electrically conductive material that transmits light. For example, the cathode electrode may be made of at least one of indium-tin oxide (ITO) and indium-zinc oxide (IZO). The example embodiment is not limited thereto.

In addition, the cathode electrode may be disposed by using a semi-transparent electrically conductive material that transmits light. For example, the cathode electrode may be made of at least one of the alloys such as LiF/Al, CsF/Al, Mg: Ag, Ca/Ag, Ca:Ag, LiF/Mg:Ag, LiF/Ca/Ag, and LiF/Ca:Ag. The example embodiment is not limited thereto.

In case that the display device 10 is a bottom-emission type display device, the cathode electrode 154 may be disposed by using an opaque electrically conductive material as a reflective electrode that reflects light. For example, the cathode electrode 154 may be made of at least one of silver (Ag), aluminum (Al), gold (Au), molybdenum (Mo), tungsten (W), chromium (Cr), and an alloy thereof.

A capping layer 155 may be disposed on the cathode electrode 154. The capping layer 155 may be formed as an organic or inorganic film that protects the cathode electrode 154 and improves external light efficiency. The capping layer 155 may be disposed as an inorganic film by using a metallic material such as LiF and further include an organic film. The example embodiments of the present disclosure are not limited thereto. For example, the capping layer 155 may have a layered structure including an organic film and an inorganic film. A thickness of the organic film and a thickness of the inorganic film may be different from each other. For example, the thickness of the organic film may be larger than the thickness of the inorganic film. As another example, the capping layer 155 may be configured as two or more layers made by stacking materials having different refractive indexes.

An encapsulation layer 160 may be disposed above the capping layer 155. The encapsulation layer 160 may protect the display device 10 from external moisture, oxygen, or foreign substances. For example, the encapsulation layer 160 may suppress the penetration of oxygen and moisture from the outside in order to suppress an oxidation of the light-emitting material and the electrode material.

The encapsulation layer 160 may be made of a transparent material that transmits light emitted from the light-emitting element layer 153.

The encapsulation layer 160 may include a first encapsulation layer 161, a second encapsulation layer 162, and a third encapsulation layer 163 that block the penetration of moisture or oxygen. The example embodiments of the present disclosure are not limited thereto. The first encapsulation layer 161, the second encapsulation layer 162, and the third encapsulation layer 163 may be structured to be alternately stacked. The example embodiments of the present disclosure are not limited thereto.

The first encapsulation layer 161 and the third encapsulation layer 163 may be made of an inorganic material including at least one of silicon nitride SiNx, silicon oxide SiOx, and aluminum oxide AlyOz. The example embodiment is not limited thereto.

The second encapsulation layer 162 may cover foreign substances or particles that may be produced during the manufacturing process. In addition, the second encapsulation layer 162 may planarize a surface of the first encapsulation layer 161.

The second encapsulation layer 162 may be made of an organic material, for example, polymer such as silicon oxycarbon SiOCz, epoxy, polyimide, polyethylene, or acrylate. The example embodiment is not limited thereto.

The third area EA, which is the end of the display device 10, may be an area in which the display device 10 is sealed by using the encapsulation layer 160 and the plurality of dams 180.

The first buffer layer 110, the second buffer layer 111, the third buffer layer 112, the first gate insulation film 113, the first interlayer insulation film 114, the first insulation film 115, the second gate insulation film 116, and the second interlayer insulation film 117, which are disposed on the substrate 100 in the first area AA and the second area NA, may extend and be disposed in the third area EA.

Lines 190 may be disposed in the third area EA so that inspection signals and touch signals for inspecting the pixel PXL of the display device 10 are communicated through the lines.

A first line 191 may be disposed on the second interlayer insulation film 117 in the third area EA.

The first line 191 may be formed by the same process as the first source/drain electrode 123. The example embodiments of the present disclosure are not limited thereto.

The first line 191 may be configured as a single layer or multilayer made of any one of molybdenum (Mo), copper (Cu), titanium (Ti), aluminum (Al) chromium (Cr), gold (Au), nickel (Ni), and neodymium (Nd) or an alloy thereof. The first line 191 may have a three-layer structure including titanium (Ti), aluminum (Al), and titanium (Ti). The example embodiments of the present disclosure are not limited thereto.

Further, a second line 192 may be disposed on the first planarization layer 118 in the third area EA.

The second line 192 may be formed by the same process as the connection electrode 125. The example embodiments of the present disclosure are not limited thereto.

The second line 192 may be configured as a single layer or multilayer made of any one of molybdenum (Mo), copper (Cu), titanium (Ti), aluminum (Al) chromium (Cr), gold (Au), nickel (Ni), and neodymium (Nd) or an alloy thereof. The second line 192 may have a three-layer structure including titanium (Ti), aluminum (Al), and titanium (Ti). The example embodiments of the present disclosure are not limited thereto.

The plurality of dams 180 may be positioned in the third area EA.

The present disclosure discloses that the dam part 180 includes the first dam 181, the second dam 182, and the third dam 183. However, the example embodiment is not limited thereto.

The first dam 181, the second dam 182, and the third dam 183 may be formed by stacking one or more insulation layers to inhibit the second encapsulation layer 162, which is formed as an organic film, from leaking to the outside of the third area EA. The example embodiments of the present disclosure are not limited thereto.

The first dam 181, the second dam 182, and the third dam 183 may have different heights and surround the first area AA and the second area NA.

Even though the second encapsulation layer 162 flows over the first dam 181, the second dam 182 and the third dam 183 may inhibit the second encapsulation layer 162 from leaking to the outside.

The first dam 181 and the second dam 182 may each have three layers including the first planarization layer 118, the bank layer 151, and the spacer 152. The third dam 183 may have two layers including the first planarization layer 118 and the bank layer 151.

The plurality of lines 190 may be disposed to extend to lower sides of the plurality of dams 180.

Further, the first planarization layer 118 may be disposed above the first line 191 in the third area EA.

The second line 192 may be disposed above the first planarization layer 118. The second line 192 may be disposed to extend to a lower side of the first dam 181 along one end of the first planarization layer 118.

The cathode electrode 154 may be disposed on the bank layer 151 in the first area AA, the second area NA, and the third area EA.

The capping layer 155 may be disposed on the cathode electrode 154 in the third area EA, and the encapsulation layer 160 may be disposed on the capping layer 155.

The first encapsulation layer 161 and the third encapsulation layer 163 of the encapsulation layer 160 may pass over the plurality of dams 180 and be disposed above the substrate 100. For example, the first encapsulation layer 161 and the third encapsulation layer 163 of the encapsulation layer 160 may pass over the plurality of dams 180 and be disposed directly above the substrate 100.

The second encapsulation layer 162 may be disposed to a part of the dam 180, such that the first encapsulation layer 161 and the third encapsulation layer 163 may be in contact with each other in the third area EA in which the second encapsulation layer 162 is not disposed.

Further, a touch layer may be disposed on the encapsulation layer 160. The touch layer may include a touch buffer film, and a touch sensor metal including a touch electrode connection line and touch electrodes.

The touch buffer film may inhibit outside moisture or a liquid chemical (a developer, an etching liquid, or the like), which is used for a process of manufacturing the touch sensor metal disposed on the touch buffer film, from being introduced into the light-emitting layer including an organic material. Therefore, the touch buffer film may suppress damage to the light-emitting layer vulnerable to a liquid chemical or moisture.

To suppress damage to the light-emitting layer including an organic material vulnerable to a high temperature, the touch buffer film may be made of an organic insulating material that may be formed at a predetermined low temperature (e.g., 100° C.) or less and have low permittivity of 1 to 3. For example, the touch buffer film may be made of an acrylic-based, epoxy-based, or siloxane-based material. The touch buffer film, which is made of an organic insulating material and has planarization performance, may suppress damage to the encapsulation layer 160 and the breakage of the touch sensor metal, which is formed on the touch buffer film, caused when the organic light-emitting display device is bent.

According to a mutual-capacitance-based touch sensor structure, the touch electrodes are disposed on the touch buffer film, and the touch electrodes are disposed to intersect each another.

The touch electrode connection line may electrically connect the touch electrodes. The touch electrode connection line and the touch electrodes may be positioned on different layers with the touch insulation film interposed therebetween.

The touch electrode connection line may be disposed to overlap the bank layer 151 and suppress a decrease in aperture ratio.

Meanwhile, the touch electrode may be electrically connected to a touch drive circuit through a touch pad as a part of the touch electrode connection line passes over an upper side and a side surface of the encapsulation layer 160 and an upper side and a side surface of the dam 180.

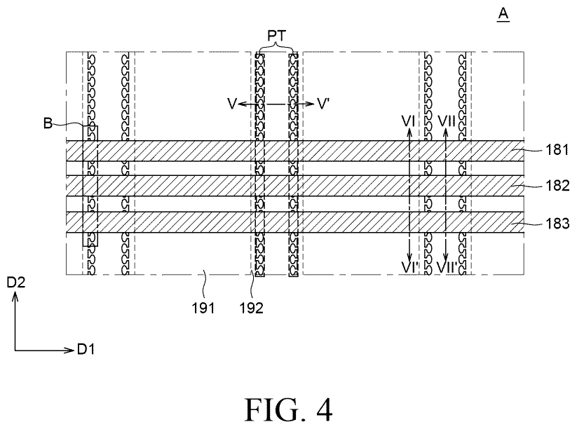

FIG. 4 is an enlarged top plan view of area A illustrated in FIG. 1.

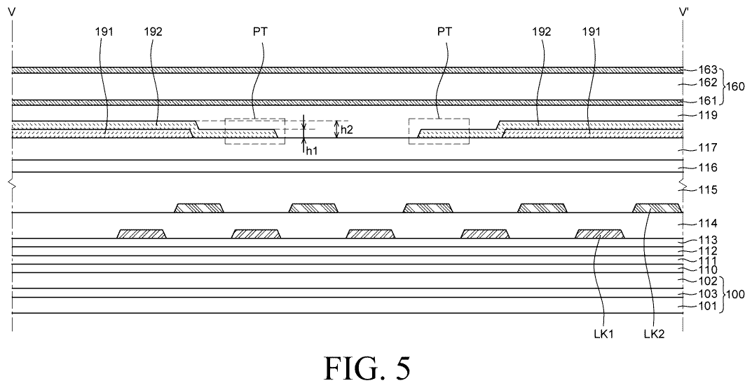

FIG. 5 is a cross-sectional view taken along line V-V′ illustrated in FIG. 4.

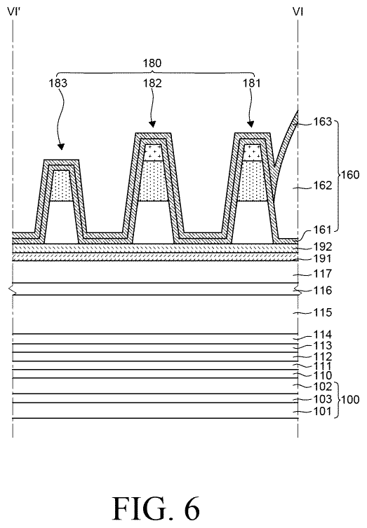

FIG. 6 is a cross-sectional view taken along line VI-VI′ illustrated in FIG. 4.

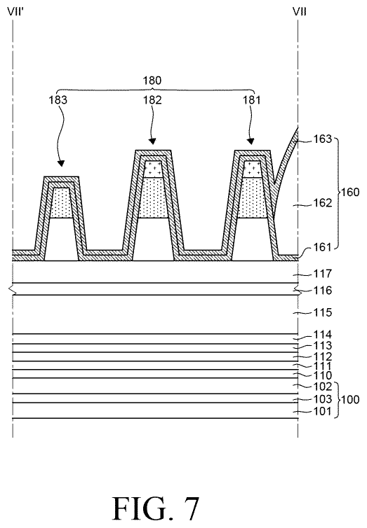

FIG. 7 is a cross-sectional view taken along line VII-VII′ illustrated in FIG. 4.

Specifically, FIG. 4 is an enlarged top plan view of the third area EA in which the plurality of dams and the plurality of lines are disposed.

Further, the substrate 100, the buffer layers 110, 111, and 112, the first gate insulation film 113, the first interlayer insulation film 114, the first insulation film 115, the second gate insulation film 116, the second interlayer insulation film 117, the second planarization layer 119, and the encapsulation layer 160 illustrated in FIGS. 5 to 7 are identical to those described with reference to FIG. 3.

With reference to FIG. 4, the plurality of dams 181, 182, and 183 may each extend in a first direction D1, and the plurality of lines 191 and 192 may each extend in a second direction D2. Therefore, the plurality of dams 181, 182, and 183 and the plurality of lines 191 and 192 may be disposed to intersect each another.

Further, with reference to FIG. 5, the second line 192 may cover a top surface and a side surface of the first line 191 and extend to a top surface of the second interlayer insulation film 117.

Further, a plurality of protruding patterns PT may be disposed outside the second line 192. That is, the plurality of protruding patterns PT may be formed on the second interlayer insulation film 117.

Because the second line 192 extends in the second direction D2, the plurality of protruding patterns PT disposed outside the second line 192 may also be disposed in the second direction D2.

Further, the second planarization layer 119 may cover and planarize the first line 191, the second line 192, and the protruding pattern PT. Further, the encapsulation layer 160 may be formed on the second planarization layer 119.

Meanwhile, a first link line LK1 may be disposed on the first gate insulation film 113, and a second link line LK2 may be disposed on the first interlayer insulation film 114. The first link line LK1 may be formed on the same layer and made of the same material as the first storage capacitor electrode 126 described with reference to FIG. 3. The second link line LK2 may be formed on the same layer and made of the same material as the second storage capacitor electrode 127 described with reference to FIG. 3.

Further, the first link line LK1 and the second link line LK2 may transmit any one of the drive voltages such as the high-potential drive voltage or the low-potential drive voltage.

Further, with reference to FIG. 6 that is a cross-sectional view of an area in which the plurality of lines 191 and 192 is disposed, the plurality of dams 180 is disposed on the plurality of lines 191 and 192. However, with reference to FIG. 7 that is a cross-sectional view of an area in which the plurality of lines 191 and 192 is not disposed, the plurality of dams 180 may be disposed on the second interlayer insulation film 117.

Further, with reference to FIGS. 6 and 7, the encapsulation layer 160 may be disposed on the plurality of lines 191 and 192 and the plurality of dams 180. More specifically, the first encapsulation layer 161, the second encapsulation layer 162, and the third encapsulation layer 163 may be disposed on the plurality of lines 191 and 192 disposed inside the first dam 181. Only the first encapsulation layer 161 and the third encapsulation layer 163 may be disposed in an outer area of the first dam 181.

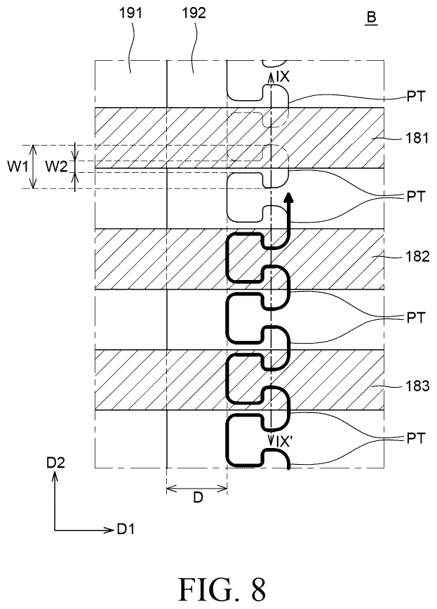

FIG. 8 is an enlarged top plan view of area B illustrated in FIG. 4.

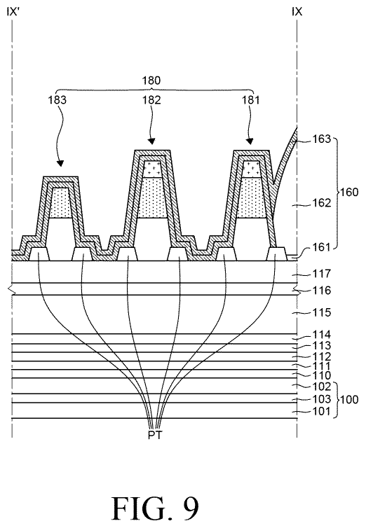

FIG. 9 is a cross-sectional view taken along line IX-IX′ illustrated in FIG. 8.

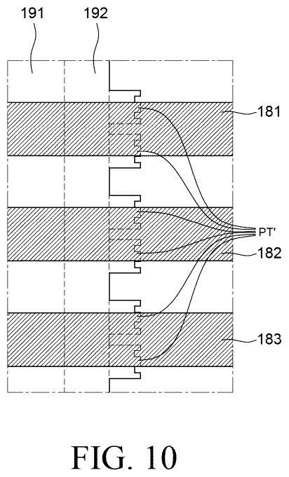

FIG. 10 is a view illustrating another type of protruding pattern of the display device according to the example embodiment of the present disclosure.

FIG. 8 is not only a view for explaining an arrangement relationship between an end of the second line 192 and an end of the first line 191 illustrated in FIG. 4, but also a view for explaining an arrangement relationship between the plurality of dams 181, 182, and 183 and the plurality of protruding patterns PT.

With reference to FIGS. 5 and 8, the end of the second line 192 is disposed outward of the end of the first line 191, and the end of the first line 191 and the end of the second line 192 are spaced apart from each other by a predetermined distance D.

With the above-mentioned arrangement relationship between the first line 191 and the second line 192, a process level difference h1 made by the first line 191 and a process level difference h2 made by the second line 192 are not formed at once, but the process level difference h2 made by the second line 192 may be formed to be spaced apart from an area in which the process level difference h1 made by the first line 191 is formed.

Therefore, the process level difference may be minimized during the process of processing the encapsulation layer 160 and the touch electrode that are the constituent elements disposed above the first line 191 and the second line 192.

Therefore, in the display device according to the example embodiment of the present disclosure, the process yield of the encapsulation layer 160 and the touch electrode, which are the constituent elements disposed above the first line 191 and the second line 192, may be improved.

Meanwhile, the plurality of protruding patterns PT may respectively protrude in extension directions of the plurality of dams 181, 182, and 183. That is, the plurality of protruding patterns PT may be arranged in the second direction D2, and the plurality of protruding patterns PT may each protrude in the first direction D1.

Further, a start portion of each of the plurality of protruding patterns PT, which is connected to the second line 192, may have a linear shape, and an end portion of each of the plurality of protruding patterns PT may have an embossed shape.

In other words, a width W2 of an area of each of the plurality of protruding patterns PT, which is adjacent to at least one 192 of the plurality of lines, may be smaller than a width W1 of an area of each of the plurality of protruding patterns PT, which is spaced apart from at least one of the plurality of lines 192.

However, the plurality of protruding patterns PT may each be limited to the embossed shape or deformed in various shapes, such as a quadrangular shape, as illustrated in FIG. 10.

Additionally, as illustrated in FIG. 10, uneven portions may be formed on outer surfaces of the plurality of protruding patterns PT.

Therefore, the plurality of protruding patterns PT connected to the second line 192 may be configured, such that lengths of the second line 192 and the outer surfaces of the plurality of protruding patterns PT may be increased.

Therefore, a moisture penetration route may be formed through the second line 192 and the outer surfaces of the plurality of protruding patterns PT, and a length of the moisture penetration route may be maximally increased.

Therefore, it is possible to improve the reliability of the display device according to the example embodiment of the present disclosure by maximally delaying the moisture penetration that occurs through the second line 192 and the outer surfaces of the plurality of protruding patterns PT.

For example, the first line 191 and the second line 192, which have no interposed inorganic film because of the second line 192 and the plurality of protruding patterns PT, may be vulnerable to moisture penetration.

Therefore, the second line 192 and the plurality of protruding patterns PT may provide the structure for delaying the moisture penetration.

Meanwhile, with reference to FIGS. 8 and 9, an end of at least one of the plurality of dams 180 may overlap the protruding pattern PT.

That is, the plurality of dams 180 may be disposed to adjoin the two adjacent protruding patterns PT. Further, the side surfaces of the plurality of dams 180 may be disposed on the top surfaces of the plurality of protruding patterns PT. Further, the first encapsulation layer 161 and the third encapsulation layer 163 may be disposed to cover all the plurality of dams 180 and the plurality of protruding patterns PT.

As described above, the plurality of dams 180 is formed to adjoin the adjacent protruding patterns PT, such that an empty space between the protruding pattern PT and the dam 180, which are adjacent to each other, may be removed.

Meanwhile, the empty space between the protruding pattern PT and the dam 180, which are adjacent to each other, may cause the occurrence of a residual film during the process of processing the encapsulation layer 160 and the touch electrode that is a post-process. The residual film is a factor that degrades the yield of the process of processing the encapsulation layer 160 and the touch electrode.

Therefore, according to the display device according to the example embodiment of the present disclosure, the empty space between the protruding pattern PT and the dam, which are adjacent to each other, may be removed, which may improve the yield of the process of processing the encapsulation layer 160 and the touch electrode that is the post-process.

In addition, in case that a residual film is produced during the process of processing the touch electrode, a current generated by a breakdown voltage flows to the residual film, which may cause a problem of the occurrence of heat generation and noise because of a fluctuation of voltages.

In the process of describing the above mentioned display device, the present disclosure actually also provides a method for manufacturing the display device. The method includes: providing a first area in which a pixel array is disposed; providing a second area in which a drive circuit configured to operate the pixel array is disposed, the second area being positioned outside the first area; and providing a third area in which a plurality of dams and a plurality of lines are disposed, the third area being positioned outside the second area, wherein a plurality of protruding patterns is formed outside at least one of the plurality of lines. The method may further include: forming uneven portions on outer surfaces of the plurality of protruding patterns. In the method, the first line and the second line can be formed using processes independent of each other. The method may further includes: by forming at least one of the plurality of dams to adjoin two adjacent protruding patterns among the plurality of protruding patterns, removing an empty space between the protruding pattern and the dam.

Therefore, according to the display device according to the example embodiment of the present disclosure, the empty space between the protruding pattern PT and the dam, which are adjacent to each other, is removed, and the residual film is not produced, such that the problem of heat generation and noise may be solved, and the reliability may be improved.

Various examples and aspects of the present disclosure are described below. These are provided as examples, and do not limit the scope of the present disclosure.

According to one or more aspects of the present disclosure, there is provided a display device. The display device includes a first area in which a pixel array is disposed; a second area in which a drive circuit configured to operate the pixel array is disposed, the second area being positioned outside the first area; and a third area in which a plurality of dams and a plurality of lines are disposed, the third area being positioned outside the second area, in which a plurality of protruding patterns is formed outside at least one of the plurality of lines.

The plurality of lines may comprise a first line and a second line that is located above the first line and that covers the first line, wherein the plurality of protruding patterns is formed outside the second line.

An end of the first line and an end of the second line may be spaced apart from each other.

The plurality of lines may be disposed below the plurality of dams, and the plurality of dams and the plurality of lines may be disposed to intersect each another.

The plurality of protruding patterns may protrude in extension directions of the plurality of dams.

In each of the plurality of protruding patterns, a width of an area adjacent to at least one of the plurality of lines may be smaller than a width of an area spaced apart from at least one of the plurality of lines.

Uneven portions may be formed on outer surfaces of the plurality of protruding patterns.

Two opposite ends of at least one of the plurality of dams overlap the plurality of protruding patterns.

An encapsulation layer may be formed on the plurality of dams and the plurality of lines.

A touch electrode may be disposed on the encapsulation layer.

The pixel array may comprise a light-emitting element; and a transistor configured to operate the light-emitting element, and wherein an anode electrode of the light-emitting element and a source/drain electrode of the transistor are connected through a connection electrode.

The first line may be formed on a same layer as the source/drain electrode of the transistor, and the second line is formed on a same layer as the connection electrode.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a first area in which a pixel array is disposed;
a second area in which a drive circuit configured to operate the pixel array is disposed, the second area being positioned outside the first area; and
a third area in which a plurality of dams and a plurality of lines are disposed, the third area being positioned outside the second area,
wherein a plurality of protruding patterns is formed outside at least one of the plurality of lines.

2. The display device of claim 1,
wherein the plurality of lines comprises:
a first line; and
a second line that is located above the first line and that covers the first line, and
wherein the plurality of protruding patterns is formed outside the second line.

3. The display device of claim 2,
wherein an end of the first line and an end of the second line are spaced apart from each other.

4. The display device of claim 1,
wherein the plurality of lines is disposed below the plurality of dams, and the plurality of dams and the plurality of lines are disposed to intersect each another.

5. The display device of claim 1,
wherein the plurality of protruding patterns protrudes in extension directions of the plurality of dams.

6. The display device of claim 1,
wherein in each of the plurality of protruding patterns, a width of an area adjacent to at least one of the plurality of lines is smaller than a width of an area spaced apart from at least one of the plurality of lines.

7. The display device of claim 1,
wherein uneven portions are formed on outer surfaces of the plurality of protruding patterns.

8. The display device of claim 1,
wherein two opposite ends of at least one of the plurality of dams overlap the plurality of protruding patterns.

9. The display device of claim 1,
wherein an encapsulation layer is formed on the plurality of dams and the plurality of lines.

10. The display device of claim 9,
wherein a touch electrode is disposed on the encapsulation layer.

11. The display device of claim 2,
wherein the pixel array comprises:
a light-emitting element; and
a transistor configured to operate the light-emitting element, and
wherein an anode electrode of the light-emitting element and a source/drain electrode of the transistor are connected through a connection electrode.

12. The display device of claim 11,
wherein the first line is formed on a same layer as the source/drain electrode of the transistor, and the second line is formed on a same layer as the connection electrode.

13. The display device according to claim 1, wherein the first area and the second area include a blocking layer disposed between a substrate and a semiconductor pattern, the blocking layer having an area larger than an area of the semiconductor pattern.

14. The display device according to claim 9, wherein the encapsulation layer includes a first encapsulation layer, a second encapsulation layer, and a third encapsulation layer stacked in sequence, and
wherein the second encapsulation layer is disposed to a portion of the plurality of dams so that the first encapsulation layer and the third encapsulation layer are in contact with each other in the third area where the second encapsulation layer is not disposed.

15. A method for manufacturing a display device, comprising:
providing a first area in which a pixel array is disposed;
providing a second area in which a drive circuit configured to operate the pixel array is disposed, the second area being positioned outside the first area; and
providing a third area in which a plurality of dams and a plurality of lines are disposed, the third area being positioned outside the second area,
wherein a plurality of protruding patterns is formed outside at least one of the plurality of lines.

16. The method of claim 15, further comprising: forming uneven portions on outer surfaces of the plurality of protruding patterns.

17. The method of claim 15, wherein a first line and a second line of the plurality of lines are formed using processes independent of each other.

18. The method of claim 15, further comprising:
by forming at least one of the plurality of dams to adjoin two adjacent protruding patterns among the plurality of protruding patterns, removing an empty space between at least one of the two adjacent protruding patterns and the at least one of the plurality of dams.
